(19) United States
(12) Patent Application Publication
(10) Pub. No.: US 2008/0023781 A1
(43) Pub. Date: Jan. 31, 2008

(54) PHOTODIODE AND MANUFACTURING METHOD OF THE SAME

(75) Inventors: Takayoshi INUJIMA, Ashigarakami-gun (JP); Mikihiko Kato, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 11/830,315

(22) Filed: Jul. 30, 2007

(30) Foreign Application Priority Data
Jul. 28, 2006 (JP) 2006-206382

(51) Int. Cl. H01L 31/0232; H01L 21/00

(52) U.S. Cl. 257/432; 438/69; 257/E31.127

(57) ABSTRACT

A lateral photodiode with increased sensitivity. The lateral photodiode includes: a substrate, a semiconductor layer, formed on the substrate, for receiving input light, an insulation layer formed on the semiconductor layer, and electrodes formed within the insulation layer. A plurality of microlenses is formed over a surface of the insulation layer (or directly on the surface) within a light receiving area of the photodiode, and the input light is focused by the microlenses in a manner so as not to be directed toward the electrodes.

### BACKGROUND OF THE INVENTION

1. Field of the Invention

This invention relates to a lateral photodiode and a manufacturing method of the same.

2. Description of the Related Art

Lateral photodiodes, in which a p-type region and an n-type region are arranged parallel to a substrate, are known as described, for example, in Japanese Unexamined Patent Publication No. 5(1993)-175536. FIG. 8 illustrates a basic structure of a lateral photodiode. In the structure, a semiconductor layer 2 for receiving input light L is formed on a substrate 1, and a p-type region 3 and an n-type region 4 are formed parallel to the substrate 1 in the semiconductor layer 2, as illustrated in the drawing. In addition, electrodes 8 and 9 are connected to the p-type region 3 and n-type region respectively, and an insulation layer 7 is formed so as to cover the semiconductor layer from above. In the lateral photodiode structured in the manner as described above, light absorption and carrier movement occur in a portion very close to the surface of the semiconductor layer, so that a high-speed operation is realized.

Generally, comb electrode structures are widely used as electrode structures of lateral photodiodes. FIG. 9 illustrates a side view of a photodiode having a comb electrode structure, and FIG. 10 illustrates a plan view of the comb electrode structure. Note that elements shown in FIG. 9 identical to those shown in FIG. 8 are given the same reference numerals. As illustrated in the drawings, the comb electrode structure is formed of thin p-type electrodes 5, each connected to each of the p-type regions 3, and thin n-type electrodes 6, each connected to each of the n-type regions 4, which are arranged alternately in a comb-like structure. This arrangement may reduce the inter-electrode capacitance, so that a high speed operation of the lateral photodiode is realized.

The employment of the comb electrode structure in a lateral photodiode, however, causes the semiconductor region to be reduced by the electrode region, and the light receiving efficiency is decreased correspondingly. As an example, if the distance between the electrodes of the comb electrode structure is 2 μm and the width of the electrodes is 1 μm, the light receiving efficiency is decreased to ⅔ in comparison with the case where the electrodes are not provided. The decrease in the light receiving efficiency naturally decreases the sensitivity of the photodiode.

The above example is described on the assumption that, in the structure illustrated in FIG. 9, the input light L is incident normal to the semiconductor layer 2. The decrease in the light receiving efficiency also occurs in the case where, for example, a multimode optical fiber is provided in the path of the input light L as shown in FIG. 9, and guided light Lg is incident on the semiconductor layer at an angle. That is, in that case, the guided light Lg represented by the dotted line may be incident on the sides of p-type electrodes and n-type electrodes, and absorbed thereby as illustrated in the drawing, as well as inputted and absorbed from the upper surfaces thereof.

So far the description has been made of the case where a comb electrode structure is employed in a lateral photodiode. Employment of another electrode structure in a lateral photodiode also causes the same problem as long as the electrode structure is provided in a light receiving area of the photodiode.

### SUMMARY OF THE INVENTION

The present invention has been developed in view of the circumstances described above, and it is an object of the present invention to increase the sensitivity of lateral photodiodes.

It is a further object of the present invention to provide a method for effectively manufacturing lateral photodiodes having such high sensitivity.

The photodiode according to the present invention is a lateral photodiode including:

a substrate;

a semiconductor layer, formed on the substrate, for receiving input light;

an insulation layer formed on the semiconductor layer;

electrodes formed within the insulation layer; and

a plurality of microlenses, formed on a surface of the insulation layer or on a surface of another layer provided on the insulation layer within a light receiving area of the photodiode, for focusing the input light in a manner so as not to be directed toward the electrodes.

The referent of “focusing the input light in a manner so as not to be directed toward the electrodes” as used herein means that the input light is focused in a direction other than toward the electrodes. Accordingly, as long as the focusing is performed in the direction described above, even the case where a portion of the input light is incident on the electrodes is included in the scope of the present invention.

Preferably, in the photodiode of the present invention, each of the plurality of microlenses is formed in a substantially hemispherical shape or a substantially half-column shape.

Further, it is particularly preferable that the photodiode of the present invention is structured based on the assumption that comb electrodes are used as the electrodes described above.

In the mean time, the photodiode manufacturing method according to the present invention is a method for manufacturing the photodiode described above, the method including the steps of:

forming protrusions, each having a shape corresponding to each of the microlens, on the semiconductor layer; and

stacking the insulation layer or the another layer on the semiconductor layer to form the microlenses raised according to the protrusions.

As described above, in a lateral photodiode in which a plurality of electrodes are formed within a light receiving area of the photodiode, input light (detection target light) is incident on the electrodes and absorbed, which leads to decrease in light receiving efficiency and degradation in sensitivity. In contrast, in the photodiode of the present invention, a plurality of microlenses is formed on a surface of the insulation layer or on a face of another layer provided on the insulation layer within a light receiving area of the photodiode for focusing the input light in a manner so as not to be directed toward the electrodes, so that the input light is prevented from being absorbed by the electrodes. This ensures improved light receiving efficiency and increased sensitivity of the photodiode.

In a lateral photodiode that employs comb electrodes, the phenomenon that the input light is absorbed by the electrodes is more likely to occur, since the light receiving area is finely divided by the comb electrodes. Thus, the application of the present invention to such photodiodes having comb electrodes may result in a significant increase in sensitivity.

Further, the present invention is widely applicable to lateral photodiodes, and particularly effective for those having a lateral pin structure, a metal-semiconductor-metal (MSM) structure, or a lateral trench structure.

In the mean time, the photodiode manufacturing method according to the present invention includes the steps of: forming protrusions, each having a shape corresponding to each of the microlens, on the semiconductor layer; and stacking the insulation layer or the another layer on the semiconductor layer to form the microlenses raised according to the protrusions. This method allows a plurality of microlenses to be formed easily, and high sensitivity lateral photodiodes to be manufactured efficiently.

### BRIEF DESCRIPTION OF THE DRAWINGS

FIG. 1 is a schematic side view of the photodiode according to a first embodiment of the present invention.

FIG. 2A is a plan view of a microlens array used in the photodiode shown in FIG. 1.

FIG. 2B is a side view of the microlens array used in the photodiode shown in FIG. 1.

FIG. 3A is a plan view of an alternative microlens array.

FIG. 3B is a side view of the alternative microlens array.

FIG. 4 is a schematic side view of the photodiode according to a second embodiment of the present invention.

FIG. 5 is a schematic side view of the photodiode according to a third embodiment of the present invention.

FIGS. 6A and 6B illustrate an operation of the photodiode shown in FIG. 5.

FIGS. 7A to 7H illustrate a method for manufacturing the photodiode shown in FIG. 5.

FIG. 8 is a schematic view of a lateral photodiode, illustrating the basic structure thereof.

FIG. 9 is a schematic side view of an example of conventional lateral photodiode.

FIG. 10 is a plan view of a comb electrode structure.

### DESCRIPTION OF THE PREFERRED EMBODIMENTS

Hereinafter, exemplary embodiments of the present invention will be described in detail with reference to the accompanying drawings.

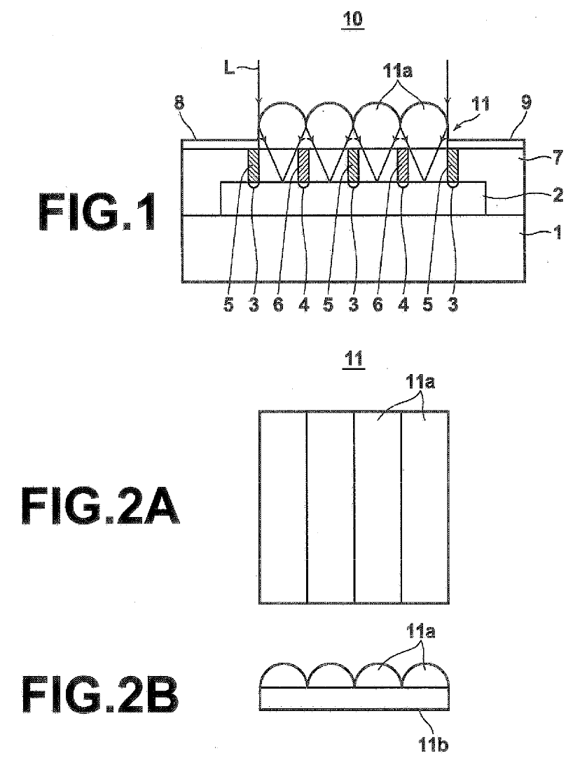

FIG. 1 is a schematic side view of the lateral photodiode 10 according to a first embodiment of the present invention. As illustrated in the drawing, the photodiode 10 includes: a substrate 1; a semiconductor layer 2, formed on the substrate 1, for receiving input light L (detection target light); p-type regions 3 and n-type regions 4 formed parallel to the substrate 1 in the semiconductor layer 2; thin p-type electrodes 5, each connected to each p-type region 3; thin n-type electrodes 4, each connected to each n-type region; a transparent insulation layer 7 formed so as to cover the semiconductor layer from above; an electrode 8 which connects a plurality of p-type electrodes 5; and an electrode 9 which connects a plurality of n-type electrodes 6.

A microlens array 11 is formed on the insulation layer 7. FIG. 1 illustrates a side cross-section shape of the microlens array 11, and planar shape and side shape are like those illustrated in FIGS. 2A and 2B respectively. That is, the microlens array 11 includes a planar transparent plate 11b on which a plurality of microlenses 11a, having a substantially half-column shape, is arranged orthogonal to the long axis direction thereof, which is formed of a transparent material, such as optical glass, plastic, or the like.

The microlenses 11a of the microlens array 11 are arranged such that a boundary portion between them is located right above the p-type electrode 5 or n-type electrode 6, and edge portions of two microlenses 11a disposed in the right and left end portions are not disposed above the p-type electrodes 5. The light receiving area of the lateral photodiode 10 substantially corresponds to the area where the entire microlens array 11 is extended.

In the lateral photodiode 10 of the present embodiment structured in the manner as described above, the input light L traveling toward the semiconductor layer 2 is focused in a manner so as not to be directed toward the p-type electrodes 5 and n-type electrodes 6 by each of the microlenses 11a of the microlens array 11, as illustrated in FIG. 1. Note that the microlens 11a of the present embodiment is so-called the cylindrical lens, so that the input light L is focused only in the plane of FIG. 1 and not in the direction orthogonal to the plane. The focusing of the input light L in the manner as described above may prevent the input light L from being absorbed by the p-type electrodes 5 and n-type electrodes 6, so that the light receiving efficiency is increased and high sensitivity of the lateral photodiode 10 is realized.

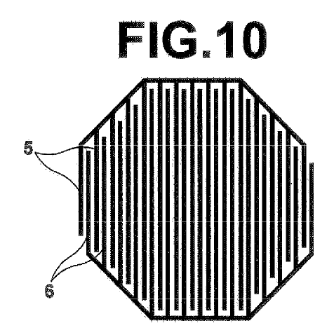

Note that the p-type electrodes 5 and n-type electrodes may be formed in an appropriate shape according to the arrangement of the p-type regions 3 and n-type regions 4. Further, such p-type electrodes 5 and n-type electrodes 6 may form a comb electrode structure like that illustrated in FIG. 10. In this case, the effect of sensitivity improvement is significant as described above.

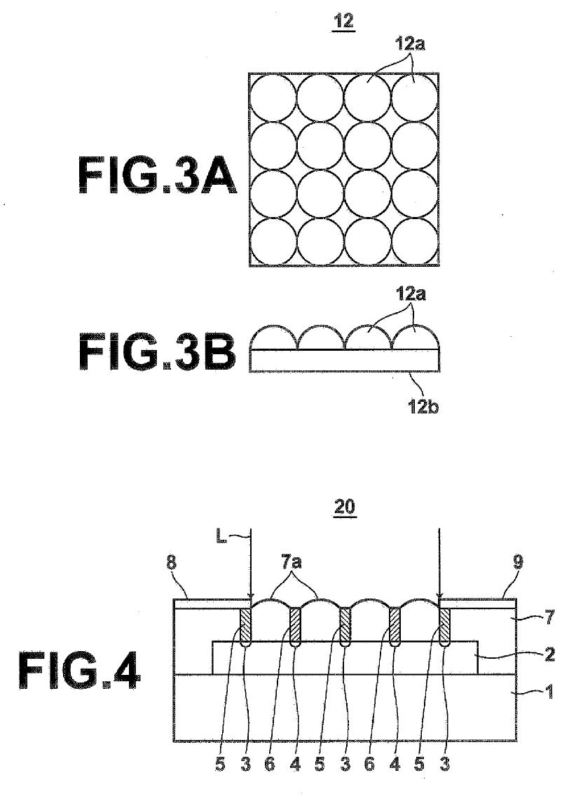

Further, instead of the microlens array 11 formed of a plurality of microlenses 11a, which are cylindrical lenses, a microlens array 12 that includes a planar transparent plate 12b on which a plurality of substantially hemispherical microlenses 12a is disposed as illustrated in FIGS. 3A and 3B may be used. The use of the microlens array 11 results in low power density of the focused light in comparison with the use of the microlens array 12, since the light is focused only in one-dimensional direction. Consequently, the use of the microlens array 11 allows reception of input light L having higher power in comparison with the use of the microlens array 12.

A second embodiment of the present invention will now be described with reference to FIG. 4. In FIG. 4, elements identical to those in FIG. 1 are given the same reference numerals and will not be elaborated upon further here unless otherwise specifically required (the same applies hereinafter).

In a photodiode 20 according to the second embodiment, a plurality of microlenses 7a is formed on the surface portion of the transparent insulation layer 7. Each of the microlenses 7a is formed in the portion between each of the p-type electrodes 5 and n-type electrodes 6, and focuses the input light L in a manner so as not to be directed to the p-type electrodes 5 and n-type electrodes 6, as in the microlenses 11a in FIG. 1. Therefore, in this case also, the input light L is prevented from being absorbed by the p-type electrodes 5 and n-type electrodes 6, so that the light receiving efficiency is increased and high sensitivity of the lateral photodiode 20 is realized.

In the present embodiment, the input light L incident normal to the upper surfaces of the p-type electrodes 5 and n-type electrodes 6 may not be prevented from being absorbed by the electrodes. In this case, however, the light incident on the side faces of the p-type electrodes 5 and n-type electrodes 6, like the guided light Lg shown in FIG. 9 or the like, may be focused, and absorption by the electrodes may be prevented. Further, not limited to such guided light Lg, if a component traveling at an angle is included in the input light L, then such component may be prevented from being absorbed from the side faces of the p-type electrodes 5 and n-type electrodes 6.

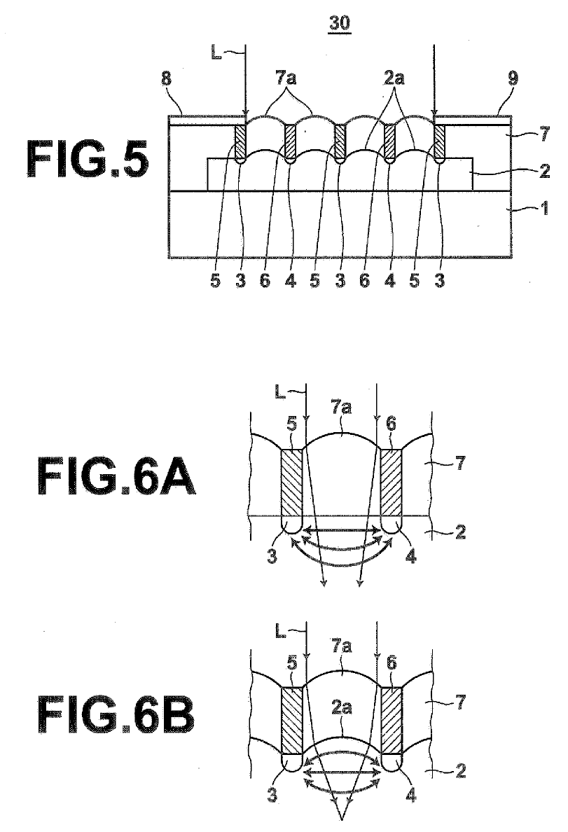

Next, a third embodiment of the present invention will be described with reference to FIG. 5. The photodiode 30 according to the third embodiment differs from the photodiode 20 shown in FIG. 4 in that it also includes microlenses 2a on the surface portion of the semiconductor layer 2, each between each of the p-type electrodes 5 and n-type electrodes 6.

In the photodiode 30 also, high sensitivity is realized by the microlenses 7a formed on the surface portion of the transparent insulation layer 7. In addition, the microlenses 2a formed on the surface portion of the semiconductor layer 2 provide further advantageous effects, which will be described in detail below.

FIG. 6A schematically illustrates a carrier movement path between each of the p-type electrodes 5 and n-type electrodes 6 in the case where the microlens 2a is not provided, while FIG. 6B schematically illustrates the carrier movement path in the case where the microlens 2a is provided. The carrier movement path is represented by the bold-line arrows in the drawings. When the microlens 2a is not provided, the carrier movement path is like that illustrated in FIG. 6A, while if the microlens 2a is provided, the input light L is focused to high power on a position closer to the surface of the semiconductor layer 2. Consequently, more carriers are formed at a position closer to the surface of the semiconductor layer 2 and move to the electrodes 5 and 6 rapidly, resulting in a high-speed response.

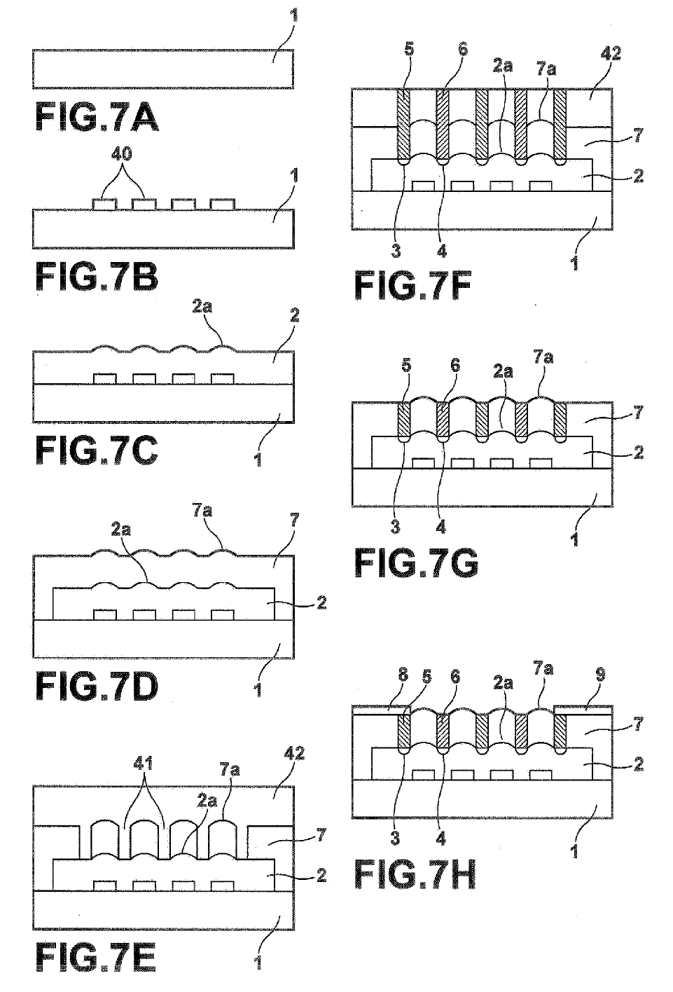

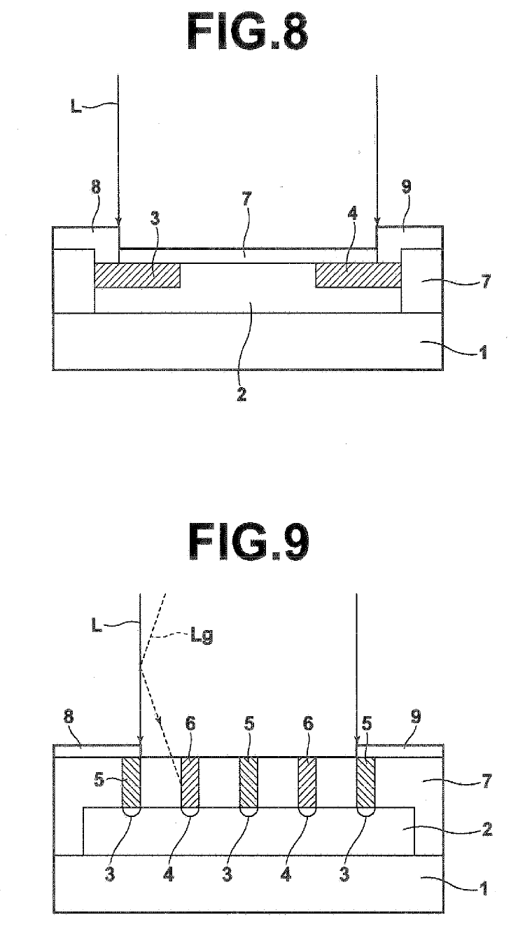

Next, a manufacturing method of the photodiode 30 will be described with reference to FIGS. 7A to 7H. Note that process steps A to H described hereinafter correspond to FIGS. 7A to 7H respectively. First, in step A, a substrate 1 is provided. Then, in step B, a plurality of protrusions 40 is formed, for example, by CVD method on the substrate 1. Next, in step C, the semiconductor layer 2 is stacked thereon, and further, in step D, the transparent insulation layer is stacked on the semiconductor layer 2. This causes microlenses 2a and 7a raised according to the protrusions 40 to be formed on the surfaces of the semiconductor layer 2 and transparent insulation layer 7 respectively. The shape of the protrusion 40 may be selected according to a desired shape of the microlens to be formed, such as rectangular shape, spindle shape, or the like.

Then, in step E, a plurality of holes 41 is created in the transparent insulation layer 7 at positions between the microlenses 2a and 7a by, for example, photolithography and etching process, and a polysilicon layer 42 is formed on the transparent insulation layer 7. Then, in step F, the p-type electrodes 5 and n-type electrodes 6 are sequentially formed in the holes 41 by ion implantation. At this time, the p-type regions 3 and n-type regions 4 are also formed in the semiconductor layer 2. Then, in step G, the polysilicon layer 42 is removed, and, in step H, electrodes 8 and 9 are formed. This completes the manufacture of the photodiode 30 described above.

When providing another layer which includes microlenses on the transparent insulation layer 7, a separately provided microlens array or the like may be attached on the transparent insulation layer 7 as in the first embodiment, or the layer may be formed on the transparent insulation layer 7 through successive stacking processes. When forming such a layer by the latter method, microlenses may be formed on the layer using the protrusions 40 described above.

In the manufacturing method described above, a plurality of protrusions 40 is provided to form microlenses 2a raised according to the protrusions (which, in turn, serve as the protrusions for forming the microlenses 7a), and microlenses 7a. Thus, a plurality of microlenses 2a and 7a is formed easily, and the high sensitivity lateral photodiode 30 is manufactured efficiently. As example materials, the following may be used: silicon for the substrate 1, germanium for the semiconductor layer 2, oxide silicon for the transparent insulation layer 7, and aluminum for the electrodes 8 and 9.

What is claimed is:

1. A lateral photodiode, comprising:
a substrate;
a semiconductor layer, formed on the substrate, for receiving input light;
an insulation layer formed on the semiconductor layer;
electrodes formed within the insulation layer; and
a plurality of microlenses, formed on a surface of the insulation layer or on a surface of another layer provided on the insulation layer within a light receiving area of the photodiode, for focusing the input light in a manner so as not to be directed toward the electrodes.

2. The photodiode as claimed in claim 1, wherein each of the plurality of microlenses is formed in a substantially hemispherical shape.

3. The photodiode as claimed in claim 1, wherein each of the plurality of microlenses is formed in a substantially half-column shape.

4. The photodiode as claimed in claim 1, wherein the electrodes are comb electrodes.

5. The photodiode as claimed in claim 2, wherein the electrodes are comb electrodes.

6. The photodiode as claimed in claim 3, wherein the electrodes are comb electrodes.

7. The photodiode as claimed in claim 1, wherein the photodiode has a lateral pin structure.

8. The photodiode as claimed in claim 1, wherein the photodiode has a metal-silicon-metal (MSM) structure.

9. The photodiode as claimed in claim 1, wherein the photodiode has a lateral trench structure.

10. A method for manufacturing the photodiode as claimed in claim 1, the method comprising the steps of:
forming protrusions, each having a shape corresponding to each of the microlens, on the semiconductor layer; and
stacking the insulation layer or the another layer on the semiconductor layer to form the microlenses raised according to the protrusions.

11. A method for manufacturing the photodiode as claimed in claim 2, the method comprising the steps of:
forming protrusions, each having a shape corresponding to each of the microlens, on the semiconductor layer; and
stacking the insulation layer or the another layer on the semiconductor layer to form the microlenses raised according to the protrusions.

12. A method for manufacturing the photodiode as claimed in claim 3, the method comprising the steps of:
forming protrusions, each having a shape corresponding to each of the microlens, on the semiconductor layer; and
stacking the insulation layer or the another layer on the semiconductor layer to form the microlenses raised according to the protrusions.

13. A method for manufacturing the photodiode as claimed in claim 4, the method comprising the steps of:
forming protrusions, each having a shape corresponding to each of the microlens, on the semiconductor layer; and
stacking the insulation layer or the another layer on the semiconductor layer to form the microlenses raised according to the protrusions.
